(19) United States
(12) Patent Application Publication
(10) Pub. No.: US 2024/0224578 A1
(43) Pub. Date: Jul. 4, 2024

(54) ELECTROLUMINESCENT DEVICE AND DISPLAY APPARATUS

(71) Applicant: BOE Technology Group Co., Ltd., Beijing (CN)

(72) Inventors: Linlin WANG, Beijing (CN); Changyen WU, Beijing (CN); Juanjuan YOU, Beijing (CN); Yongqi SHEN, Beijing (CN); Bin BU, Beijing (CN); Wenfeng SONG, Beijing (CN); Guang YAN, Beijing (CN); Li SUN, Beijing (CN); Dacheng ZHANG, Beijing (CN)

(21) Appl. No.: 18/556,850

(22) PCT Filed: Oct. 22, 2021
(86) PCT No.: PCT/CN2021/125655

§ 371 Date: Oct. 23, 2023

(30) Foreign Application Priority Data
Apr. 26, 2021 (CN) 202110454429.8

(51) Int. Cl. H10K 50/818; H10K 50/16; H10K 50/17; H10K 50/82; H10K 50/852; H10K 102/00

(52) U.S. Cl. CPC H10K 50/818; H10K 50/16; H10K 50/171; H10K 50/82; H10K 50/852; H10K 2102/351

(57) ABSTRACT

An electroluminescent device and a display apparatus, for improving the efficiency and prolonging the service life of the electroluminescent device. The electroluminescent device comprises: an anode comprising a reflective material; a cathode arranged opposite to the anode and comprising a transflective material; n light-emitting functional layers laminated between the anode and the cathode, wherein n is an integer greater than 1; and each light-emitting functional layer comprises a light-emitting layer and an electron transport layer located at the side of the light-emitting layer close to the cathode, wherein the thickness of the electron transport layer in the light-emitting functional layer closest to the cathode is greater than that of the electron transport layers in the remaining light-emitting functional layers; and (n−1) charge generation layers located between two adjacent light-emitting functional layers.

### CROSS REFERENCE TO RELATED APPLICATION

This application is a National Stage of International Application No. PCT/CN2021/125655, filed Oct. 22, 2021, which claims priority to Chinese Patent Application No. 202110454429.8, filed to the China National Intellectual Property Administration on Apr. 26, 2021, the entire contents of which are incorporated herein by reference.

### TECHNICAL FIELD

The present disclosure relates to the field of display technology, in particular to an electroluminescent device and display apparatus.

### BACKGROUND

Organic Light Emitting Diodes (OLEDs) are active light emitting display devices and therefore have an unparalleled ultra-high contrast ratio and ultra-fast response speed. At present, the mass-produced large-size OLED products all adopt the way of white light OLEDs and color filters, which makes the power consumption and color gamut very insufficient. The use of blue light OLEDs with green and red quantum dot color conversion layers can greatly improve the above problems, and can achieve high resolution, high color gamut, high color purity, and does not having a viewing angle dependence. In order to improve the display quality of the display, the way of adding green and red quantum dot color conversion layers to the blue light OLED usually adopts a laminated blue light device. However, in the related art, the efficiency and lifespan of the laminated blue light device are relatively low.

### SUMMARY

Embodiments of the present disclosure provide an electroluminescent device and a display apparatus for improving the efficiency and lifespan of the electroluminescent device.

The embodiments of the present disclosure provide an electroluminescent device, the electroluminescent device include: an anode, including a reflective material; a cathode, arranged opposite to the anode, and including a transflective material; n light-emitting functional layers, laminated between the anode and the cathode; wherein n is an integer greater than 1; each of the n light-emitting functional layers includes: a light-emitting layer, and an electron transport layer at a side of the light-emitting layer close to the cathode; and a thickness of an electron transport layer in a light-emitting functional layer closest to the cathode is greater than each of thicknesses of electron transport layers in remaining light-emitting functional layers; and (n−1) charge generation layer between two light-emitting functional layers adjacent to each other.

In some embodiments, a ratio of the thickness of the electron transport layer in the light-emitting functional layer closest to the cathode to a thickness of an electron transport layer in any one of the remaining light-emitting functional layers ranges from 1.5 to 2.

In some embodiments, n is greater than 2, and thicknesses of the (n−1) charge generation layers are the same.

In some embodiments, the thicknesses of the electron transport layers in the remaining light-emitting functional layers are the same, except for the electron transport layer in the light-emitting functional layer closest to the cathode.

In some embodiments, the electron transport layer includes: an electron transport sub-layer; and a hole blocking layer between the electron transport sub-layer and the light-emitting layer; and a thickness of a hole-blocking layer in the light-emitting functional layer closest to the cathode is greater than each of thicknesses of hole blocking layers in the remaining light-emitting functional layers.

In some embodiments, the thickness of the electron transport layer in the light-emitting functional layer closest to the cathode is greater than a thickness of the light-emitting layer in the light-emitting functional layer closest to the cathode; a thickness of the electron transport layer in each of the remaining light-emitting functional layers except for the light-emitting functional layer closest to the cathode is smaller than thickness of the light-emitting layer in each of the remaining light-emitting functional layers except for the light-emitting functional layer closest to the cathode.

In some embodiments, the light-emitting functional layer closest to the cathode further includes: an electron injection layer between the electron transport layer and the cathode; and the electron injection layer at least includes two materials, and the cathode includes at least one material of the electron injection layer.

In some embodiments, a cavity length L of a resonant cavity of the electroluminescence device ranges from (0.78λ-10) nanometers to (0.78λ-30) nanometers; and λ is an emission wavelength of the light-emitting layer in the light-emitting functional layer.

In some embodiments, a material of the cathode includes magnesium and silver; and a content ratio of the magnesium to the silver ranges from 1:9 to 2:8.

In some embodiments, a thickness of the cathode ranges from 100 angstroms to 150 angstroms.

In some embodiments, the anode includes: a light-transmitting conductive layer with a thickness ranging from 100 angstroms to 200 angstroms; and a reflective layer at a side of the light-transmitting conductive layer away from the cathode.

In some embodiments, the electroluminescent device further includes: a capping layer, at a side of the cathode away from the anode; and an optical distance of the capping layer ranges from 1100 angstroms to 1300 angstroms.

In some embodiments, the light-emitting layers in different light-emitting functional layers emit light with the same color.

In some embodiments, a color of the light emitted by the light-emitting layers is blue.

The embodiments of present disclosure provide a display apparatus, and the display apparatus includes the electroluminescent device provided by the embodiments of the present disclosure.

### BRIEF DESCRIPTION OF FIGURES

In order to illustrate technical solutions of embodiments of the present disclosure more clearly, drawings needing to be used in descriptions of the embodiments will be introduced below briefly. Apparently, the drawings described below are only some embodiments of the present disclosure, and those ordinarily skilled in the art can further obtain other drawings according to these drawings without inventive efforts.

FIG. 1 is a schematic structural diagram of an electroluminescent device provided by an embodiment of the present disclosure.

FIG. 2 is a comprehensive spectrum comparison diagram for electroluminescent devices provided by an embodiment of the present disclosure.

FIG. 3 is a schematic structural diagram of another electroluminescent device provided by an embodiment of the present disclosure.

### DETAILED DESCRIPTION

In order to make the purpose, technical solutions and advantages of the embodiments of the present disclosure clearer, the technical solutions of the embodiments of the present disclosure will be clearly and completely described below in conjunction with drawings of the embodiments of the present disclosure. Apparently, the described embodiments are parts of the embodiments of the present disclosure, not all of the embodiments. In addition, the embodiments and the features of the embodiments in the present disclosure can be combined with each other without conflict. Based on the embodiments of the present disclosure, all other embodiments obtained by those ordinarily skilled in the art without creative work shall fall within the claimed scope of the present disclosure.

Unless otherwise defined, technical or scientific terms used in the present disclosure shall have the ordinary meanings as understood by those with ordinary skills in the art to which the present disclosure belongs. “First”, “second” and similar words used in the present disclosure do not indicate any order, quantity or importance, but are only used to distinguish different components. “Comprise” or “include” or other similar words mean that the element or item appearing before the word encompasses the element or item listed after the word and its equivalents, but does not exclude other elements or items. “Connecting” or “connected” or similar words are not limited to physical or mechanical connections, but may include electrical connections, whether direct or indirect.

It should be noted that the dimensions and shapes of the figures in the drawings do not reflect the real scale, and are only intended to illustrate the present disclosure. In addition, the same or similar reference numerals refer to the same or similar elements or elements having the same or similar functions throughout.

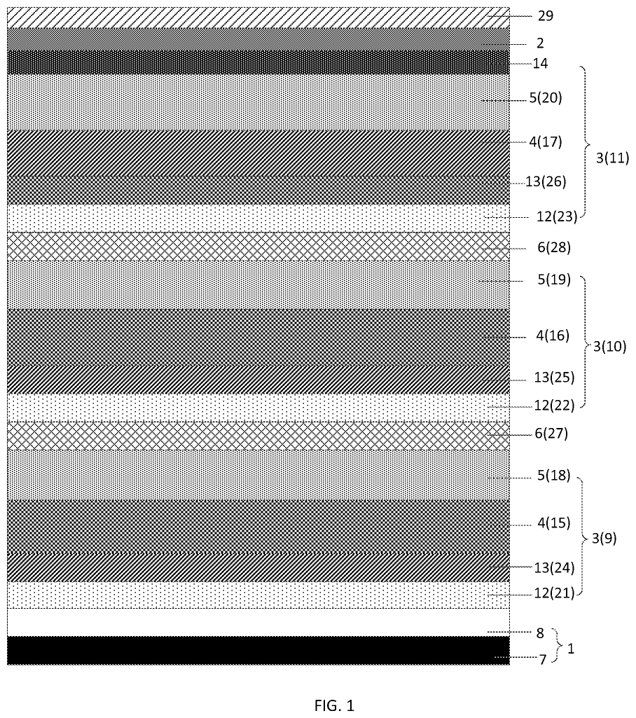

The embodiments of the present disclosure provide an electroluminescent device, and as shown in FIG. 1, the electroluminescent device includes: an anode 1, including a reflective material; a cathode 2, arranged opposite the anode 1, and including a transflective material; n light-emitting functional layers 3, laminated between the anode 1 and the cathode 2, where n is an integer greater than 1; each of the n light-emitting functional layers including: a light-emitting layer 4, and an electron transport layer 5 at a side of the light-emitting layer 4 close to the cathode 2; where a thickness of an electron transport layer 5, in a light-emitting functional layer 5, closest to the cathode 2 is greater than a thickness of a electron transport layer 5 in each of remaining light-emitting functional layers 3; and (n−1) charge generation layers 6 between two light-emitting functional layers 3 adjacent to each other.

In the electroluminescent device provided by the embodiments of the present disclosure, the anode includes the reflective material, and the cathode includes the transflective material, so that an optical resonant cavity is formed between the anode and the cathode, and multiple light-emitting functional layers are arranged between the anode and the cathode in a laminated manner, which can improve the luminous intensity of the electroluminescent device. In addition, in general, the electron injection efficiency of the cathode is higher than that of the charge generation layer, so that the thickness of the electron transport layer in the light-emitting functional layer closest to the cathode is greater than each of the thicknesses of the electron transport layers in the remaining light-emitting functional layers, which can balance the electron injection efficiency of the different light-emitting functional layers, optimize the luminous efficiency of the electroluminescent device, and also improve the lifespan of the electroluminescent device.

In some embodiments, the ratio of the thickness of the electron transport layer in the light-emitting functional layer closest to the cathode to a thickness of an electron transport layer in any one of the remaining light-emitting functional layers ranges from 1.5 to 2.

In some embodiments, as shown in FIG. 1, n is greater than 2, and the thicknesses of the (n−1) charge generation layers 6 are the same.

In this way, the respective charge generation layers are provided the same electron generation ability, which can further balance the electron injection efficiency of different light-emitting functional layers, improve the luminous efficiency of the electroluminescent device, and improve the lifespan of the electroluminescent device.

It should be noted that, in FIG. 1, n is equal to 3 as an example for description, that is, three light-emitting functional layers are laminated. As shown in FIG. 1, the three light-emitting functional layers 3 specifically include: a first light-emitting functional layer 9, a second light-emitting functional layer 10 at a side of the first light-emitting functional layer 9 away from the anode 1, and a third light-emitting functional layer 11 at a side of the second light-emitting functional layer 10 away from the first light-emitting functional layer 9. The first light-emitting functional layer 9 includes a first light-emitting layer 15 and a first electron transport layer 18. The second light-emitting functional layer 10 includes a second light-emitting layer 16 and a second electron transport layer 19. The third light-emitting functional layer 11 includes a third light-emitting layer 17 and a third electron transport layer 20. The third light-emitting functional layer 11 is the light-emitting functional layer closest to the cathode, that is, the thickness of the third electron transport layer 20 is greater than the thickness of the second electron transport layer 19, and the thickness of the third electron transport layer 20 is greater than the thickness of the first electron transport layer 18. A first charge generation layer 27 is between the first light-emitting functional layer 9 and the second light-emitting functional layer 10, and a second charge generation layer 28 is between the second light-emitting functional layer 10 and the third light-emitting functional layer 11. The thickness of the first charge generation layer 27 is equal to the thickness of the second charge generation layer 28.

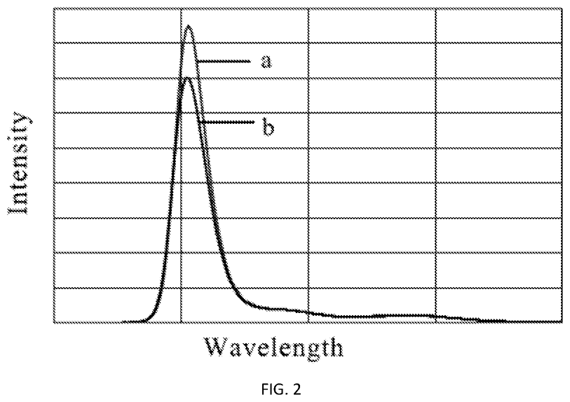

Next, the spectrum of the electroluminescent device with the thickness of the third electron transport layer greater than the thickness of the second electron transport layer and the spectrum of the electroluminescent device with the thickness of the third electron transport layer smaller than the thickness of the second electron transport layer are compared. The comprehensive spectrum comparison diagram for the electroluminescent devices is shown in FIG. 2, wherein the curve a represents the spectrum of the electroluminescent device with the thickness of the third electron transport layer greater than the thickness of the second electron transport layer, and the curve b represents the spectrum of the electroluminescent device with the thickness of the third electron transport layer smaller than the thickness of the second electron transport layer. It can be seen from FIG. 2 that the luminous intensity of the light-emitting device corresponding to the curve a is higher than that of the light-emitting device corresponding to the curve b.

In some embodiments, as shown in FIG. 1, except for the electron transport layer 5 in the light-emitting functional layer 3 closest to the cathode 2, the electron transport layers 5 in the remaining light-emitting functional layers 3 have the same thickness.

In the electroluminescent device provided by the embodiments of the present disclosure, since the charge generation layers have the same thickness, the charge generation layers are provided with the same electron generation capacity, so that the thicknesses of the remaining electron transport layers except the electron transport layer closest to the cathode are the same, which can further balance the electron injection efficiency of different light-emitting functional layers, improve the light-emitting efficiency of the electroluminescent device, and improve the lifespan of the electroluminescent device.

In a specific implementation, when the electroluminescent device includes three light-emitting functional layers, as shown in FIG. 1, the thickness of the first electron transport layer 18 is equal to the thickness of the second electron transport layer 19.

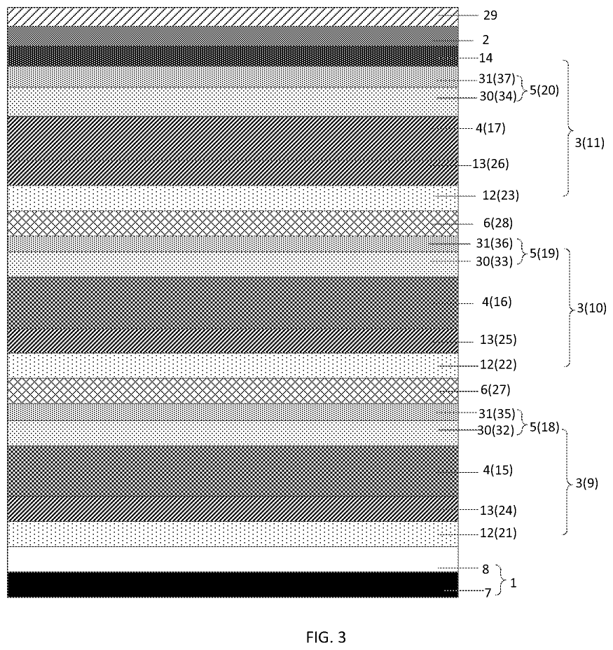

In some embodiments, as shown in FIG. 3, the electron transport layer 5 includes: an electron transport sub-layer 31; and a hole blocking layer 30 between the electron transport sub-layer 31 and the light-emitting layer 4; a thickness of a hole blocking layer 30 in the light-emitting functional layer 3 closest to the cathode 2 is greater than a thickness of the hole blocking layer 30 in each of the remaining light-emitting functional layers 3.

It should be noted that the electron mobility of the hole blocking layer is smaller than that of the electron transport sub-layer. When the hole blocking layer is thicker, the electron injection is likely to deteriorate. In the electroluminescent device provided by the embodiments of the present disclosure, the thickness of the hole blocking layer in the light-emitting functional layer closest to the cathode is greater than the thickness of the hole-blocking layer in each of the remaining light-emitting functional layers, to avoid the deterioration of the electron injection of the light-emitting functional layer closer to the charge generation layer, to balance the electron injection efficiency of the electroluminescent device, and to improve the luminous efficiency of the electroluminescent device and the lifespan of the electroluminescent device.

As shown in FIG. 3, the first electron transport layer 18 includes a first electron transport sub-layer 35 and a first hole blocking layer 32. The second electron transport layer 19 includes: a second electron transport sub-layer 36, and a second hole blocking layer 33. The third electron transport layer 20 includes: a third electron transport sub-layer 37, and a third hole blocking layer 34. The thickness of the first hole blocking layer 32 is greater than that of the second hole blocking layer 33, and the thickness of the first hole blocking layer 32 is greater than that of the third hole blocking layer 34.

In some embodiments, as shown in FIG. 3, the thickness of the second hole blocking layer 33 is smaller than the thickness of the third hole blocking layer 34.

In some embodiments, as shown in FIG. 1 and FIG. 3, in the light-emitting functional layer 3 closest to the cathode 2, the thickness of the electron transport layer 5 is greater than the thickness of the light-emitting layer 4; and in each of the remaining light-emitting functional layers 3 other than the light-emitting functional layer 3 closest to the cathode 2, the thickness of the electron transport layer 5 is smaller than the thickness of the light-emitting layer 4.

In the electroluminescent device provided by the embodiments of the present disclosure, the thickness of the electron transport layer in the light-emitting functional layer closest to the cathode is greater than the thickness of the light-emitting layer in the light-emitting functional layer closest to the cathode, so that the distance between the cathode and the light-emitting layer can be increased, and a serious surface plasmon polaritons (SPP) effect occurred at the interface between the cathode and the other medium can be avoided, and the reduction of luminous efficiency caused by the SPP effect can be avoided. That is, the luminous efficiency of the electroluminescent device can be improved.

As shown in FIG. 1 and FIG. 3, the thickness of the third electron transport layer 20 is greater than the thickness of the third light-emitting layer 17.

In some embodiments, as shown in FIG. 1 and FIG. 3, the light-emitting functional layer 3 closest to the cathode 2 further includes: an electron injection layer 14 between the electron transport layer 5 and the cathode 2; the electron injection layer 14 at least includes two materials, and the cathode includes at least one material of the electron injection layer.

That is, in the electroluminescent device provided by the embodiments of the present disclosure, the cathode and the electron injection layer in contact with each other include at least one same material, so that the energy level difference at the interface between the cathode and the electron injection layer can be reduced, which is beneficial to improve the electron injection efficiency, improve the luminous efficiency of the electroluminescent device, and improve the lifespan of the electroluminescent device.

In specific implementation, the electron injection layer may be prepared by co-evaporating two materials, for example, one of the two materials may be the same as one of the materials included in the cathode.

In some embodiments, the thickness of the electron injection layer is less than 15 angstroms.

In some embodiments, the material of the cathode includes magnesium (Mg) and silver (Ag); the content ratio of the magnesium to silver ranges from 1:9 to 2:8.

It should be noted that, the stronger the oscillation of the resonant cavity is, the higher the luminous efficiency of the electroluminescent device is, and the narrower the spectrum of the emergent light of the electroluminescent device is. When the cathode material includes Mg and Ag, the effect of the hole injection is good when there is more Mg and less Ag, and the reflectivity of the resonant cavity is higher when there is less Mg and more Ag, and the higher the reflectivity, the stronger the oscillation of the resonator.

In the electroluminescent device provided by the embodiments of the present disclosure, the content ratio of magnesium to silver ranges from 1:9 to 2:8, so that the oscillation effect of the resonant cavity and the hole injection efficiency of the cathode can be balanced, and the luminous efficiency of the electroluminescence device can be improved.

In some embodiments, the content ratio of the magnesium to silver is 2:8.

In a specific implementation, when the cathode includes magnesium and silver, and the cathode and the electron injection layer include a same material, the electron injection layer includes, for example, magnesium.

In some embodiments, the thickness of the cathode ranges from 100 angstroms to 150 angstroms.

In some embodiments, a cavity length L of the resonant cavity of the electroluminescent device ranges from (0.78λ-10) nanometers to (0.78λ-30) nanometers; where, λ is the emission wavelength of the light-emitting layer in the light-emitting functional layer.

It should be noted that the cavity length of the resonant cavity of the electroluminescent device affects the luminous efficiency of the electroluminescent device. In the electroluminescent device provided by the embodiments of the present disclosure, the cavity length L of the resonant cavity of the electroluminescent device ranges from (0.78λ-10) nanometers to (0.78λ-30) nanometers, which can further improve the luminous efficiency of the electroluminescent device under the condition that the emission wavelength of the light-emitting layer is constant.

In some embodiments, as shown in FIG. 1 and FIG. 3, the anode 1 includes: a light-transmitting conductive layer 8; and a reflective layer 7 at a side of the light-transmitting conductive layer 8 away from the cathode 2.

In some embodiments, a thickness of the light-transmitting conductive layer ranges from 100 angstroms to 200 angstroms, the material of the light-transmitting conductive layer includes indium tin oxide; and the material of the reflective layer includes silver.

In this way, that is, the indium tin oxide is adjacent to the light-emitting functional layer, since the work function of the indium tin oxide is higher than that of an electrode made of a single metal, the hole injection capability of the electroluminescent device can be improved.

Of course, in some embodiments, the anode may also include a single layer, and the material of the anode may also include: silver or aluminum alloy.

In some embodiments, as shown in FIG. 1 and FIG. 3, the electroluminescent device further includes: a capping layer 29 at a side of the cathode 2 away from the anode 1.

In some embodiments, the optical distance of the capping layer 29 ranges from 1100 angstroms to 1300 angstroms.

In the electroluminescent device provided by the embodiments of the present disclosure, the capping layer is at the side of the cathode away from the anode, so that the reduction of luminous efficiency caused by the SPP effect can be further avoided.

In some embodiments, the light-emitting layers in different light-emitting functional layers emit light with the same color.

In some embodiments, the color of the light emitted by the light-emitting layer is blue.

Of course, in some embodiments, the color of the light emitted by the light-emitting layer may also be red or green.

The embodiments of the present disclosure provide a display apparatus, and the display apparatus includes the electroluminescent device provided by the embodiments of the present disclosure.

In a specific implementation, the display apparatus includes a plurality of sub-pixels arranged in an array, and each sub-pixel includes at least one of the above electroluminescent devices provided in the embodiments of the present disclosure.

That is, the display apparatus provided by the embodiments of the present disclosure is an electroluminescence display apparatus.

In a specific implementation, the electroluminescent device can be, for example, an organic light-emitting diode device.

In some embodiments, the display apparatus further includes: a substrate, and a quantum dot layer; where the electroluminescent device is at a side of the substrate, and the quantum dot layer is at a side of the electroluminescent device away from the substrate.

That is, the display apparatus provided by the embodiments of the present disclosure realizes the display through the organic light-emitting diode device and the quantum dot chromatic color resist.

In some embodiments, the quantum dot layer includes quantum dot color resists that correspond one-to-one with the emission colors of the sub-pixels.

In the display apparatus provided by the embodiments of the present disclosure, each sub-pixel includes the electroluminescent device provided in the embodiments of the present disclosure, and in the electroluminescent device, the thickness of the electron transport layer in the light-emitting functional layer closest to the cathode is larger than the thicknesses of the remaining light-emitting functional layers, which can balance the electron injection efficiency of different light-emitting functional layers and optimize the luminous efficiency of the electroluminescent device, thereby improving the brightness of the light emitted by electroluminescent device, so that the luminous intensity of the electroluminescent device is concentrated in the specific wavelength range excited by the quantum dot, the emission intensity of the sub-pixels can be improved, thereby reducing the power consumption of the display apparatus.

In some embodiments, the sub-pixels include: a red sub-pixel, a blue sub-pixel, and a green sub-pixel.

In some embodiments, the red sub-pixel, the blue sub-pixel and the green sub-pixel each includes a blue electroluminescent device. That is, the color of the light emitted by the light-emitting layers of the electroluminescent devices in the red sub-pixel, the blue sub-pixel and the green sub-pixel is blue.

Correspondingly, in some embodiments, the red sub-pixel includes a red quantum dot color resist, and the green sub-pixel includes a green quantum dot color resist.

It should be noted that the red quantum dot color resist is excited by blue light to emit red light, and the green quantum dot color resist is excited by blue light to emit green light.

In the display apparatus provided by the embodiments of the present disclosure, each sub-pixel includes the above-mentioned blue light electroluminescent device provided by the embodiments of the present disclosure. Since the blue light electroluminescent device has an emission spectrum with a narrow half-wave width, it is convenient to improve the emission intensity of blue light and color purity. In addition, the thickness of the electron transport layer in the light-emitting functional layer closest to the cathode is greater than the thicknesses of the electron transport layers in the remaining light-emitting functional layers, so that the light-emitting brightness of the blue light electroluminescent device can be improved, and the luminous intensity of the electroluminescent device can be concentrated in a specific wavelength range excited by the red quantum dots or the green quantum dots, the emission intensity of the red sub-pixel and the green sub-pixel can be improved, thereby reducing the power consumption of the display apparatus.

The display apparatus provided by the embodiments of the present disclosure is any product or component with a display function, such as a mobile phone, a tablet computer, a television, a display, a notebook computer, a digital photo frame, and a navigator. Other essential constituent parts of the display apparatus should be understood by those of ordinary skill in the art, which are not repeated here, and should it not limit the present disclosure. The implementation of the display apparatus may refer to the embodiments of the above electroluminescent device, and the repetition is omitted.

To sum up, in the electroluminescent device and the display apparatus provided by the embodiments of the present disclosure, the anode includes a reflective material, and the cathode includes a transflective material, so that an optical resonant cavity is formed between the anode and the cathode, and multiple light-emitting functional layers are arranged between the anode and the cathode in a laminated manner, which can improve the luminous intensity of the electroluminescent device. In addition, in general, the electron injection efficiency of the cathode is higher than that of the charge generation layer, so that the thickness of the electron transport layer in the light-emitting functional layer closest to the cathode is greater than the thicknesses of the electron transport layers in the remaining light-emitting functional layers, which can balance the electron injection efficiency of the different light-emitting functional layer, optimize the luminous efficiency of the electroluminescent device, and can also improve the lifespan of the electroluminescent device.

Apparently, those skilled in the art can make various changes and modifications to the embodiments of the present invention without departing from the spirit and scope of the embodiments of the present invention. In this way, if the modifications and variations of the embodiments of the present invention fall within the scope of the claims of the present invention and equivalent technologies, the present invention also intends to include these modifications and variations.

1. An electroluminescent device, wherein the electroluminescent device comprises:
an anode, comprising a reflective material;
a cathode, opposite the anode, and comprising a transflective material;
n light-emitting functional layers, laminated between the anode and the cathode; wherein n is an integer greater than 1; each of the n light-emitting functional layers comprises: a light-emitting layer, and an electron transport layer at a side of the light-emitting layer close to the cathode; wherein a thickness of an electron transport layer in a light-emitting functional layer closest to the cathode is greater than each of thicknesses of electron transport layers in remaining light-emitting functional layers; and
(n−1) charge generation layers between two light-emitting functional layers adjacent to each other.

2. The electroluminescent device according to claim 1, wherein a ratio of the thickness of the electron transport layer in the light-emitting functional layer closest to the cathode to a thickness of an electron transport layer in any one of the remaining light-emitting functional layers ranges from 1.5 to 2.

3. The electroluminescent device according to claim 1, wherein n is greater than 2, and thicknesses of the (n−1) charge generation layers are the same.

4. The electroluminescent device according to claim 3, wherein the thicknesses of the electron transport layers in the remaining light-emitting functional layers are the same, except for the electron transport layer in the light-emitting functional layer closest to the cathode.

5. The electroluminescent device according to claim 1, wherein the electron transport layer comprises:
an electron transport sub-layer; and
a hole blocking layer between the electron transport sub-layer and the light-emitting layer;
wherein a thickness of a hole-blocking layer in the light-emitting functional layer closest to the cathode is greater than each of thicknesses of hole blocking layers in the remaining light-emitting functional layers.

6. The electroluminescent device according to claim 1, wherein: the thickness of the electron transport layer in the light-emitting functional layer closest to the cathode is greater than a thickness of the light-emitting layer in the light-emitting functional layer closest to the cathode; a thickness of the electron transport layer in each of the remaining light-emitting functional layers except for the light-emitting functional layer closest to the cathode is smaller than the thickness of the light-emitting layer in each of the remaining light-emitting functional layers except for the light-emitting functional layer closest to the cathode.

7. The electroluminescent device according to claim 1, wherein the light-emitting functional layer closest to the cathode further comprises:
an electron injection layer between the electron transport layer and the cathode; wherein the electron injection layer at least comprises two materials, and the cathode comprises at least one material of the electron injection layer.

8. The electroluminescence device according to claim 1, wherein a cavity length L of a resonant cavity of the electroluminescence device ranges from (0.78λ-10) nanometers to (0.78λ-30) nanometers; and
wherein, λ is an emission wavelength of the light-emitting layer in the light-emitting functional layer.

9. The electroluminescent device according to claim 1, wherein a material of the cathode comprises magnesium and silver; and a content ratio of the magnesium to the silver ranges from 1:9 to 2:8.

10. The electroluminescent device according to claim 9, wherein a thickness of the cathode ranges from 100 angstroms to 150 angstroms.

11. The electroluminescent device according to claim 1, wherein the anode comprises:
a light-transmitting conductive layer with a thickness ranging from 100 angstroms to 200 angstroms; and
a reflective layer at a side of the light-transmitting conductive layer away from the cathode.

12. The electroluminescent device according to claim 1, further comprising:
a capping layer at a side of the cathode away from the anode; wherein an optical distance of the capping layer ranges from 1100 angstroms to 1300 angstroms.

13. The electroluminescent device according to claim 1, wherein the light-emitting layers in different light-emitting functional layers emit light with a same color.

14. The electroluminescent device according to claim 13, wherein a color of the light emitted by the light-emitting layers is blue.

15. A display apparatus, comprising the electroluminescent device according to claim 1.

16. The electroluminescent device according to claim 7, wherein the thickness of the electron injection layer is less than 15 angstroms.

17. The electroluminescent device according to claim 11, wherein a material of the light-transmitting conductive layer includes indium tin oxide.

18. The electroluminescent device according to claim 11, wherein a material of the reflective layer includes silver.

19. The electroluminescent device according to claim 11, wherein a material of the anode includes silver or aluminum alloy.

20. The electroluminescent device according to claim 13, wherein a color of the light emitted by the light-emitting layers is red or green.
